(19) United States
(12) Patent Application Publication
(10) Pub. No.: US 2019/0372474 A1
(43) Pub. Date: Dec. 5, 2019

(54) ENERGY CONVERTING DEVICE, AND DEVICE FOR ENERGIZING OIL EXPLORATION DEVICE

(71) Applicant: General Electric Company, Schenectady, NY (US)

(72) Inventors: Saijun MAO, Shanghai (CN); Stewart Blake BRAZIL, Niskayuna, NY (US)

(21) Appl. No.: 16/487,297

(22) PCT Filed: Feb. 23, 2018
(86) PCT No.: PCT/US2018/019485

§ 371 Date: Aug. 20, 2019

(30) Foreign Application Priority Data
Feb. 23, 2017 (CN) 201710100001.7

(51) Int. Cl. H02M 7/00; H05K 1/18; H01F 27/28

(52) U.S. Cl. CPC H02M 7/003; H01F 2027/2809; H01F 27/2804; H05K 1/181

(57) ABSTRACT

An energy converting device comprises an energy converting circuit which is provided on a substrate and configured to convert an input direct voltage into an output direct voltage higher than the input direct voltage, wherein the substrate comprises a first layer and a second layer. The energy converting circuit comprises a plurality of semiconductor devices and a planar transformer. Each of the semiconductor devices is in a flat shape and mounted on the substrate. The planar transformer comprises a primary circuit arranged on the first layer and a secondary circuit arranged on the second layer. The secondary circuit is insulated from the primary circuit by an insulation layer between the first and second layers.

### BACKGROUND

Embodiments of the present disclosure relate generally to energy converting devices, and more particularly to devices for energizing oil exploration devices.

In recent years, with development of oil and gas industry, demands for oil and gas exploration and production are increasing, which requires downhole measurement equipment and power supply of higher qualities. Since downhole environment is very harsh, the downhole power supply needs to have good heat resistance, good pressure resistance, good vibration resistance and a compact size.

However, the conventional downhole power supply usually has a large size, and may not adapt well to the downhole harsh environment.

Therefore, it is desirable to provide new energy converting devices and devices for energizing the oil exploration device to solve at least one of the above-mentioned problems.

### BRIEF DESCRIPTION

In one aspect, an energy converting device comprises an energy converting circuit which is provided on a substrate and configured to convert an input direct voltage into an output direct voltage higher than the input direct voltage, wherein the substrate comprises a first layer and a second layer. The energy converting circuit comprises a plurality of semiconductor devices and a planar transformer. Each of the semiconductor devices is in a flat shape and mounted on the substrate. The planar transformer comprises a primary circuit arranged on the first layer and a secondary circuit arranged on the second layer. The secondary circuit is insulated from the primary circuit by an insulation layer between the first and second layers.

In another aspect, a device for energizing an oil exploration device comprises a power source configured to provide an input direct voltage, and an energy converting circuit. The energy converting circuit is coupled between the power source and the oil exploration device and configured to convert the input direct voltage into an output direct voltage which is higher than the input direct voltage and provided to the oil exploration device (200). The energy converting circuit is arranged on a substrate comprising a first layer and a second layer. The energy converting circuit comprises a plurality of semiconductor devices, each in a flat shape and mounted on the substrate. The energy converting circuit further comprises a planar transformer. The planar transformer comprises a primary circuit arranged on the first layer, and a secondary circuit arranged on the second layer. The second layer is insulated from the primary circuit by an insulation layer between the first and second layers.

In another aspect, an energy converting device is provided on a substrate, wherein the substrate comprises a first layer, a second layer, a third layer, and a fourth layer. The energy converting device comprises an inverter circuit, a transformer circuit and a voltage-multiplier circuit. The inverter circuit is configured to invert an input direct voltage into a first alternating voltage. The inverter circuit comprises inverter components, each of which is in a flat shape and mounted onto a surface of the first layer. The transformer circuit is configured to transform the first alternating voltage into a second alternating voltage, wherein the second alternating voltage has an amplitude larger than the first alternating voltage. The transformer circuit comprises a primary circuit arranged on the second layer, and a secondary circuit arranged on the third layer. The secondary circuit is insulated from the primary circuit by an insulation layer between the second and third layers. The voltage-multiplier circuit is configured to convert the second alternating voltage into an output direct voltage having a value larger than a peak value of the second alternating voltage. The voltage-multiplier circuit comprises voltage-multiplier components, each of which is in a flat shape and mounted onto a surface of the fourth layer.

### DRAWINGS

These and other features, aspects, and advantages of the present disclosure will become better understood when the following detailed description is read with reference to the accompanying drawings in which like characters represent like parts throughout the drawings, wherein:

FIG. 1 is a sketch view of a device for energizing an oil exploration device in accordance with an exemplary embodiment of the present disclosure;

FIG. 2 is a sketch view of an energy converting device in accordance with an exemplary embodiment of the present disclosure; and

FIG. 3 is a sketch view of an energy converting device in accordance with another exemplary embodiment of the present disclosure.

### DETAILED DESCRIPTION

In an effort to provide a concise description of these embodiments, not all features of an actual implementation are described in one or more specific embodiments. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of the present disclosure.

Unless defined otherwise, technical and scientific terms used herein have the same meaning as is commonly understood by one of ordinary skill in the art to which the present disclosure belongs. The terms “first,” “second,” “third,” “fourth,” and the like, as used herein do not denote any order, quantity, or importance, but rather are used to distinguish one element from another. Also, the terms “a” and “an” do not denote a limitation of quantity, but rather denote the presence of at least one of the referenced items. The term “or” is meant to be inclusive and mean either any, several, or all of the listed items. The use of “including,” “comprising,” or “having,” and variations thereof herein are meant to encompass the items listed thereafter and equivalents thereof as well as additional items.

Embodiments of the present disclosure refer to a device for energizing an oil exploration device, which is able to work well in downhole environment, and thus can be widely applied in oil exploration and production.

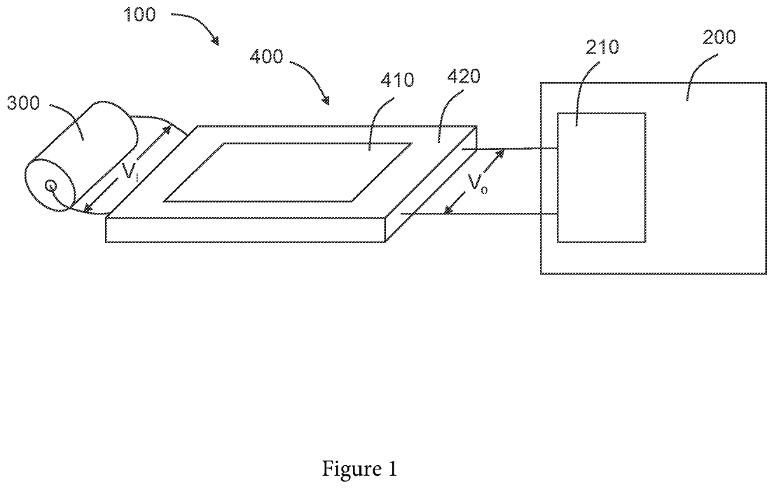

FIG. 1 shows a sketch view of a device 100 for energizing an oil exploration device 200. As shown in FIG. 1, the device 100 comprises a power source 300, and an energy converting device 400 coupled between the power source 300 and the oil exploration device 200. The power source 300 is configured to provide an input direct voltage V_{I} to the energy converting device 400. The energy converting device 400 is configured to receive the input direct voltage V_{I} from the power source 300 and convert the input direct voltage V_{I} into an output direct voltage Vₒ which is higher than the input direct voltage V_{I}. The output direct voltage is provided to the oil exploration device 200 for energizing it.

The energy converting device 400 comprises a substrate 420 and an energy converting circuit 410 provided on the substrate 420. The energy converting circuit 410 is connected between the power source 300 and the oil exploration device 200, and configured to convert the input direct voltage V_{I} into the output direct voltage Vₒ. In some embodiments, the input direct voltage V_{I} is in a range from about 12 to about 400 volts (V), and the output direct voltage Vₒ is in a range from about 10 to about 1000 kilovolts (kV).

In some embodiments, at least a part of the energy converting circuit 410 is printed on the substrate 420, and the energy converting device 400 is configured as a printed circuit board. The printed circuit board 400 may be a multi-layer board comprising a plurality of layers laminated together, each layer having a part of the energy converting circuit printed thereon.

In some embodiments, the oil exploration device 200 comprises a neutron generator 210. The device 100 is coupled with the neutron generator 210 for energizing the neutron generator 210. Specifically, the energy converting circuit 410 is connected between the power source 300 and the neutron generator 210. The neutron generator mentioned hereinafter refers to a neutron source device which contains linear accelerators and that produce neutrons by fusing isotopes of hydrogen together. In some embodiments, the device 100 and the neutron generator 210 is mounted in a drill pipe, and configured to measure the well while drilling.

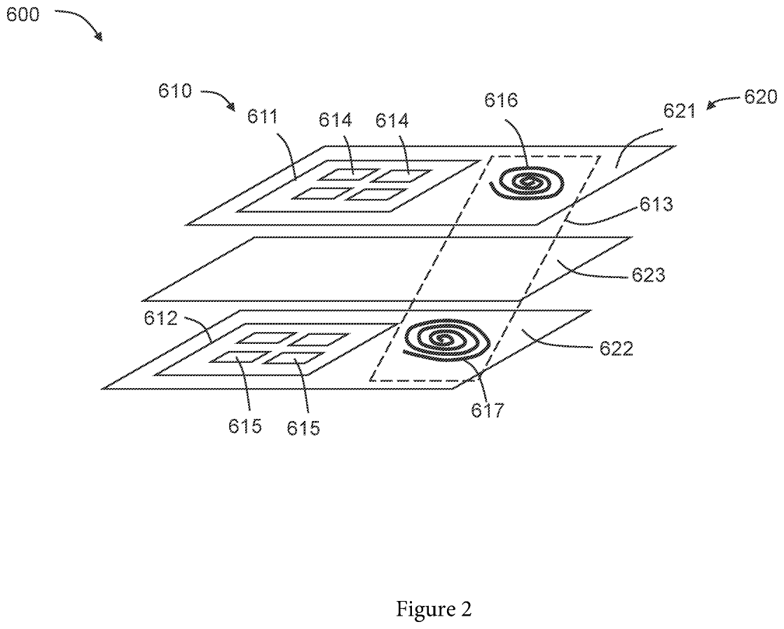

FIG. 2 shows a sketch view of an energy converting device 600 that is similar to the energy converting device 400 and can be used in a device like the device 100, in accordance with an exemplary embodiment of the present disclosure. The energy converting device 600 comprises an energy converting circuit 610 provided on a substrate 620. Referring to FIG. 2, the substrate 620 of the energy converting device comprises a first layer 621, a second layer 622, and an insulation layer 623 between the first and second layers. The energy converting circuit 610 comprises an inverter circuit 611, a transformer circuit 613, and a voltage-multiplier circuit 612.

The inverter circuit 611 is arranged on the first layer 621 and configured to invert the input direct voltage into a first alternating voltage. At least a part of the inverter circuit 611 is printed on the first layer 621. As shown in FIG. 2, the inverter circuit 611 comprises inverter components 614, each of which is in a flat shape and mounted onto a surface of the first layer 621. The inverter circuit 611 further comprises inverter connecting wires which are printed on the first layer 621 and configured to interconnect the inverter components 614. The flat shape mentioned hereinafter refers to a shape with little thickness, wherein the thickness may be uniform or nonuniform, and an object in the flat shape may have smooth or unsmooth surface.

The transformer circuit 613 is configured to transform the first alternating voltage into a second alternating voltage, wherein the second alternating voltage has an amplitude larger than the first alternating voltage. Specifically, the transformer circuit 613 comprises a primary circuit 616 arranged on the first layer 621 and a secondary circuit 617 arranged on the second layer 622. The secondary circuit 617 is insulated from the primary circuit 616 by the insulation layer 623. The primary circuit 616 and the secondary circuit 617 overlap in a direction perpendicular to the substrate 620, in such a manner that the primary circuit and the secondary circuit are coupled electromagnetically.

In some embodiments, the insulation layer 623 is made of a material comprising polypropylene, polytetrafluoroethylene and a combination thereof. The insulation layer 623 has a thickness in a range from about 0.1 to about 5 millimeters (mm). Each of the first and second layers is made of a dielectric composite material, which may comprise epoxy resin, woven, glass fibers, ceramics or a combination thereof.

In some embodiments, the transformer circuit 613 is configured in a planar transformer. Specifically, at least a part of the primary circuit is printed on the first layer 621, and the other part of the primary circuit is in a flat shape and mounted on the first layer 621. Similarly, at least a part of the secondary circuit is printed on the second layer 622, and the other part of the secondary circuit is in a flat shape and mounted on the second layer 622. In some embodiments, as shown in FIG. 2, the part of the primary circuit printed on the first layer 621 is in a shape of spiral 616, and the part of the secondary circuit printed on the second layer 622 is in a shape of spiral 617.

The voltage-multiplier circuit 612 is arranged on the second layer 622 and configured to convert the second alternating voltage into the output direct voltage which has a value larger than a peak value of the second alternating voltage. As shown in FIG. 2, the voltage-multiplier circuit 612 comprises voltage-multiplier components 615, each of which is in a flat shape and mounted onto a surface of the second layer 622. The voltage-multiplier circuit 612 further comprises voltage-multiplier connecting wires printed on the second layer and configured to interconnect the voltage-multiplier components 615.

The inverter components 614 and the voltage-multiplier components 615 may comprise semiconductor devices. The semiconductor device is made of a material comprising silicon carbide, i.e., the semiconductor device is a silicon carbide device. The silicon carbide device has a maximum operating temperature in a range from about 150 to about 250 degrees centigrade (° C.) and a maximum operating pressure in a range from about 30 to about 40 kilopascals (kPa), so the silicon carbide device can work normally in the downhole environment. In some embodiments, the silicon carbide device comprises a silicon carbide transistor, a silicon carbide diode, or a combination thereof, wherein the silicon carbide transistor comprises a silicon carbide field effect transistor.

Arrangements of the inverter circuit and the voltage-multiplier circuit are not limited to the above embodiment. In some embodiments, the inverter circuit and the primary circuit may be provided on different layers, and the voltage-multiplier circuit and the secondary circuit may also be provided on different layers. Or, the inverter circuit, the primary circuit and the voltage-multiplier circuit may be provided on a same layer. In this case, all the semiconductor devices are mounted on a surface of the same layer.

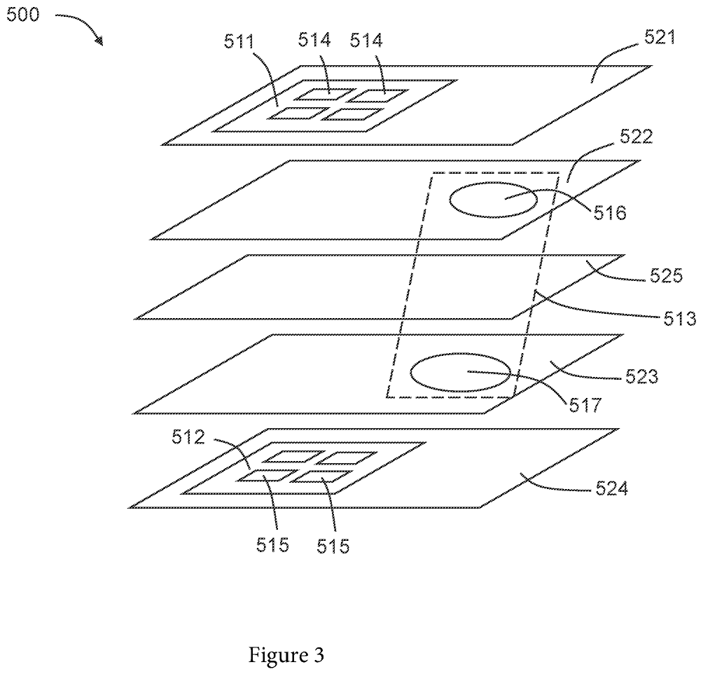

FIG. 3 shows a sketch view of an energy converting device 500 that is similar to the energy converting device 400 and can be used in a device like the device 100, in accordance with another exemplary embodiment of the present disclosure. The energy converting device 500 comprises an energy converting circuit provided on a substrate. Referring to FIG. 3, the substrate of the energy converting device comprises a first layer 521, a second layer 522, a third layer 523, a fourth layer 524, and an insulation layer 525 between the third and fourth layers. The energy converting circuit of the energy converting device comprises an inverter circuit 511, a transformer circuit 513, and a voltage-multiplier circuit 512. The function of the inverter circuit 511, the transformer circuit 513, and the voltage-multiplier circuit 512 are respectively similar to the inverter circuit 611, the transformer circuit 613, and the voltage-multiplier circuit 612 illustrated in FIG. 2, which will not be repeated here.

As shown in FIG. 3, the inverter circuit 511 is arranged on the first layer 521, and the inverter circuit 511 comprises a plurality of inverter components 514, each of which is in a flat shape and mounted onto a surface of the first layer 521. The inverter circuit 511 further comprises an inverter connecting wires printed on the first layer and configured to interconnect the inverter components 514.

The transformer circuit 513 comprises a primary circuit 516 on the second layer 522, and a secondary circuit 517 on the third layer 523. The secondary circuit 517 is insulated from the primary circuit 516 by the insulation layer 525 between the second and third layers. Structures of the primary circuit 516, the secondary circuit 517 and the insulation layer 525 are respectively similar to the primary circuit 616, the secondary circuit 617 and the insulation layer 623 illustrated in FIG. 2, which will not be repeated here.

The voltage-multiplier circuit 512 is arranged on the fourth layer 524, and the voltage-multiplier circuit 512 comprises voltage-multiplier components 515, each of which is in a flat shape and mounted onto a surface of the fourth layer 524. The voltage-multiplier circuit 512 further comprises a voltage-multiplier connecting wires printed on the fourth layer 524 and configured to interconnect the voltage-multiplier components 515.

In some embodiments, the first layer, the second layer, the insulation layer, the third layer, and the fourth layer with the circuits thereon are laminated in order in a thickness direction of the substrate, and form a printed circuit board with multiple layers.

As will be understood by those familiar with the art, the present disclosure may be embodied in other specific forms without depending from the spirit or essential characteristics thereof. Accordingly, the disclosures and descriptions herein are intended to be illustrative, but not limiting, of the scope of the disclosure which is set forth in the following claims.

1. An energy converting device (400, 600), comprising:
an energy converting circuit (610), provided on a substrate (620) and configured to convert an input direct voltage (V_{I}) into an output direct voltage (Vₒ) higher than the input direct voltage, wherein the substrate (620) comprises a first layer (621) and a second layer (622), and the energy converting circuit comprises:
a plurality of semiconductor devices (614, 615), each in a flat shape and mounted on the substrate, and
a planar transformer (613), comprising:
a primary circuit (616) arranged on the first layer (621), and
a secondary circuit (617) arranged on the second layer (622) and insulated from the primary circuit by an insulation layer (623) between the first and second layers.

2. The device according to claim 1, wherein the primary circuit (616) and the secondary circuit (617) overlap in a direction perpendicular to the substrate.

3. The device according to claim 1, wherein the insulation layer (623) is made of a material comprising polypropylene, polytetrafluoroethylene and a combination thereof.

4. The device according to claim 1, wherein the input direct voltage is in a range from about 12 to about 400 volts, and the output direct voltage is in a range from about 10 to about 1000 kilovolts.

5. The device according to claim 1, wherein the semiconductor device (614, 615) is made of a material comprising silicon carbide, each semiconductor device has a maximum operating temperature in a range from about 150 to about 250 degrees centigrade and a maximum operating pressure in a range from about 30 to about 40 kilopascals.

6. The device according to claim 1, wherein at least one of the semiconductor devices (614) is mounted onto a surface of the first layer, and the other semiconductor device(s) (615) is mounted onto a surface of the second layer.

7. The device according to claim 1, wherein all of the semiconductor devices (614, 615) are mounted on a surface of the first layer or the second layer.

8. A device (100) for energizing an oil exploration device (200), comprising:
a power source (300), configured to provide an input direct voltage; and
an energy converting circuit (410, 610), coupled between the power source (300) and the oil exploration device (200) and configured to convert the input direct voltage (V_{I}) into an output direct voltage (Vₒ) which is higher than the input direct voltage and provided to the oil exploration device (200), wherein the energy converting circuit (610) is arranged on a substrate (620) comprising a first layer (621) and a second layer (622), and the energy converting circuit (610) comprises:
a plurality of semiconductor devices (614, 615), each in a flat shape and mounted on the substrate, and
a planar transformer, comprising:
a primary circuit (616) arranged on the first layer (621), and
a secondary circuit (617) arranged on the second layer (622) and insulated from the primary circuit (616) by an insulation layer (623) between the first and second layers.

9. The device according to claim 8, wherein the oil exploration device (200) comprises a neutron generator (210), and the energy converting circuit (410) is coupled between the power source (300) and the neutron generator (210).

10. An energy converting device (500) provided on a substrate, wherein the substrate comprises a first layer, a second layer, a third layer, and a fourth layer, the energy converting device comprising:
an inverter circuit (511), configured to invert an input direct voltage into a first alternating voltage, wherein the inverter circuit (511) comprises inverter components (514), each of which is in a flat shape and mounted onto a surface of the first layer (521);
a transformer circuit (513), configured to transform the first alternating voltage into a second alternating voltage, wherein the second alternating voltage has an amplitude larger than the first alternating voltage, and the transformer circuit (513) comprises:
a primary circuit (516) arranged on the second layer (522), and
a secondary circuit (517) arranged on the third layer (523) and insulated from the primary circuit (516) by an insulation layer (525) between the second and third layers; and
a voltage-multiplier circuit (512), configured to convert the second alternating voltage into an output direct voltage having a value larger than a peak value of the second alternating voltage, wherein the voltage-multiplier circuit (512) comprises voltage-multiplier components (515), each of which is in a flat shape and mounted onto a surface of the fourth layer (524).
